(19) United States
(12) Patent Application Publication
(10) Pub. No.: US 2002/0006693 A1
(43) Pub. Date: Jan. 17, 2002

(54) Semiconductor device and the manufacturing method thereof

(75) Inventor: Tomoko Matsuda, Tokyo (JP)

Correspondence Address: SUGHRUE, MION, ZINN, MACPEAK & SEAS, 2100 Pennsylvania Avenue, N.W., Washington, DC, 20037, US

(73) Assignee: NEC CORPORATION

(21) Appl. No.: 09/902,704

(22) Filed: Jul. 12, 2001

(30) Foreign Application Priority Data
Jul. 13, 2000 (JP) 212841/2000

(51) Int. Cl. H01L 21/338

(52) U.S. Cl. 438/180; 438/184

(57) ABSTRACT

A manufacturing method that prevents an enhanced diffusion while preventing channeling from occurring, and forms a local channel having a steep impurity concentration distribution with precise positioning. After forming a sacrifice film on the surface of a silicon substrate, ion implantation is performed from a perpendicular direction through a resist film mask to form a local channel. The thickness of the sacrifice film is greater than or equal to 10 nm and less than or equal to 100 nm. Indium is used as an ion species of the ion implantation.

### BACKGROUND OF THE INVENTION

1. Field of the Invention

The present invention relates to a technique to form a local channel in a region under a gate electrode of a transistor. The present application is based on Japanese Patent Application No. 202841/2000, which is incorporated herein by reference.

2. Background

During the implantation of ions into a silicon substrate, it is important to prevent the phenomenon of channeling, which occurs when an ion is implanted deeper than designed. This phenomenon is disclosed in patents such as Japanese Patent Application Laid-open No. Heisei 9-135025. The conventional method to prevent channeling is to implant ions at an angle relative to the silicon substrate. In this method, the implantation angle of an ion is shifted from a direction perpendicular to the semiconductor substrate, and the implanted ion collides with the crystal lattice. As a result, it is difficult for channeling to occur. For example, when a silicon (100) crystal is used as a substrate, by shifting the implantation angle about 7 degrees from the direction perpendicular to the semiconductor substrate, channeling is effectively prevented.

On the other hand, due to the miniaturization of transistors, a technique to form a local channel in a region just under a gate electrode of a MOS transistor has been considered recently. The local channel, for example, is a high impurity concentration region that has the same conductivity type as a well formed adjacent to the source and drain regions of a transistor, and especially adjacent to an extension region. FIGS. 1A and 1B show one form of a local channel. In FIGS. 1A and 1B, an n-type well 7 is formed in a silicon substrate 1 and a drain region 21b and an extension region 18d are formed. A gate electrode 16 is formed on the surface of a substrate through the gate insulating film 17, and a sidewall 19b is formed so as to contact the sides of the gate electrode 16 and the gate insulating film 17. A local channel 14 is formed so as to contact with a portion of the drain region 21b and the extension region 18d. In the conventional transistor shown in FIG. 1B, a parasitic resistance is generated due to the spread 23 of a diffusion layer 21b because the distribution of the impurity concentration at the edge of the source and drain regions does not abruptly decrease. The spread 23 of the diffusion layer 21b shown as a dotted line in FIG. 1B. In addition, short channel effects increase as well. If the local channel 14 is formed as shown in FIG. 1A, the spread of the diffusion layer can be prevented and the above problems can be solved.

In order to form a local channel, it is necessary to perform an ion implantation with a resist film mask formed on a semiconductor substrate. Accordingly, when an angle implantation is performed, it is difficult to form the local channel in the desired position because the blind portion of the resist film interferes with the ion implantation. Under these circumstances, when the local channel is formed, it is necessary to make the angle of the ion implantation substantially perpendicular to the semiconductor substrate. Because of this reason, a channeling prevention method other than angle implantation is required when forming the local channel. In particular, for the formation of the local channel, a steep impurity concentration distribution and accurate positioning as designed are necessary, and it is especially important to prevent the occurrence of channeling.

Moreover, when the local channel is formed, it is important to prevent the occurrence of enhanced diffusion of the impurity subsequent to the ion implantation. After the ion implantation, a heat treatment is generally performed to dissolve lattice defects, and to activate the impurities. In this process, the initial impurity concentration distribution may change because the implanted impurities move. This phenomenon is called enhanced diffusion. If enhanced diffusion occurs, the steep decrease of the impurity concentration distribution is lost, and the impurity concentration distribution differs from the one designed. The result of enhanced diffusion is that the local channel will not function satisfactorily. In order to prevent the occurrence of enhanced diffusion, a heavy element such as indium from Group III, and arsenic or phosphorus from Group V can be effectively used. However, employment of a heavy element causes the generation of channeling. Under these circumstances, in the conventional technique of the formation of the local channel, it is difficult to prevent the occurrence of both channeling and enhanced diffusion, and a steep impurity concentration distribution is difficult to obtain.

The present invention has been made in view of the above-mentioned circumstances. Therefore, the invention prevents the occurrence of enhanced diffusion and channeling, while forming a steep impurity concentration distribution with precise positioning. More particularly, the invention provides a technique of forming a local channel as designed, in order to prevent short-channel effects.

### SUMMARY OF THE INVENTION

A first aspect of the present invention provides a method of manufacturing a semiconductor device, comprising providing a sacrifice film having a thickness greater than or equal to 10 nm and less than or equal to 100 nm on a surface of a semiconductor substrate. The first aspect of the invention further provides forming a resist film having, an opening, on top, and providing impurity doped regions by performing an ion implantation through the sacrifice film from a direction perpendicular to the semiconductor substrate using, the resist film as a mask.

A second aspect of the present invention provides a method of manufacturing a semiconductor device, comprising providing a sacrifice film on a semiconductor substrate, and providing a resist film having an opening on top. The second aspect of the present invention also provides impurity doped regions by performing, an ion implantation through the sacrifice film from the direction perpendicular to the semiconductor substrate using the resist film as a mask. The method provides that the equation d≧0.035V+4.75 is satisfied during the ion implantation, where d (nm) is the thickness of the sacrifice film and V (keV) is the implant energy upon the ion implantation.

In the above-mentioned manufacturing method of a semiconductor device, because the ion implantation is performed from a direction substantially perpendicular to the semiconductor substrate, a problems caused by the blind resist can be eliminated, and an impurity doped region may be accurately provided at the desired position. Moreover, the ion implantation is performed through a thick sacrifice film, thereby effectively preventing the occurrence of channeling.

The reason why channeling may be prevented with the thick sacrifice film as described above is because an incident ion collides with an element composing the sacrifice film and then scatters. FIG. 2 shows this state. The incident ion that enters in a direction perpendicular to the semiconductor substrate changes its direction when it collides with an atom composing a sacrifice film 3. As a result, the same state arises as the case that an angle implantation is performed, so the ion is implanted into the substrate with a tilted angle from the vertical direction. Therefore, channeling is effectively prevented. Moreover, a relatively heavy element, which can easily channel, but hardly causes the enhanced diffusion, may be selected as an impurity for forming a local channel. As a result, it is possible to prevent the occurrence of enhanced diffusion while preventing channeling, and to realize the steep impurity concentration distribution with a precision positioning. Here, the steep impurity concentration distribution is a distribution that has an abrupt decrease in the impurity concentration gradient from a peak of the impurity concentration position to a depthwise of the substrate. Referring to FIG. 3, an impurity concentration distribution (described later in Embodiment 1) of a sacrifice film with the thickness of greater than or equal to 10 nm decreases with a concentration gradient of 8×10⁵ atoms/cm³ in indium concentration as going away from the surface of the substrate. According to the present invention, it is possible to realize such a steep impurity concentration distribution.

A third aspect of the present invention provides a semiconductor substrate, comprising a sacrifice film having a thickness greater than or equal to 10 nm and less than or equal to 100 nm is provided in an element forming surface. The third aspect provides a resist film having an opening is provided on the sacrifice film.

A fourth aspect of the present invention provides a semiconductor substrate, characterized in that a sacrifice film for an ion implantation is provided on the surface of the semiconductor substrate. A resist film having an opening is provided on the sacrifice film, and that d≧0.035V+4.75 is satisfied where d (nm) is the thickness of the sacrifice film and V (keV) is the implant energy upon the ion implantation.

A thick sacrifice film is provided on the semiconductor substrate and a resist film mask is provided on top of the sacrifice film. Therefore, performing an ion implantation from a direction perpendicular to the semiconductor substrate through the sacrifice film using the resist film mask, an impurity doped region having a steep impurity concentration distribution can be suitably provided. In particular, this technique is preferably used to provide an impurity-doped region with a precise position such as a local channel in which abruptness of the impurity concentration distribution is necessary.

A fifth aspect of the present invention provides a semiconductor device comprising a gate electrode provided on a semiconductor substrate, source and drain regions provided at both sides of the gate electrode, and a local channel having a conductivity type opposite to the source and drain regions. The local channel includes indium as an impurity.

In this semiconductor device, the local channel is formed so that the local channel contacts with the source and drain regions, and therefore, the parasitic resistance is small, and short-channel effects are effectively suppressed. The local channel includes indium as an impurity, and therefore, the fluctuation of the impurity concentration distribution due to factors such as heat is small, and a steep impurity concentration distribution can be obtained. In the conventional technique, it was difficult to form a local channel using indium due to the channeling problem. However, such a local channel can be obtained by using the above-mentioned manufacturing method according to the present invention.

### BRIEF DESCRIPTION OF THE DRAWINGS

The above and other objects, advantages and features of the present invention will be more apparent from the following description taken in conjunction with the accompanying drawings, in which:

FIG. 1A is a diagram illustrating a function of a local channel;

FIG. 1B is a diagram illustrating a function of a local channel;

FIG. 2 is a sectional view illustrating a function of the present invention;

FIG. 3 is a graph showing the relationship between the thickness of the sacrifice film and the impurity concentration distribution;

FIG. 4 is sectional view of an example of a semiconductor device according to the present invention;

FIG. 5A is a sectional view of an example of a semiconductor device according to the present invention;

FIG. 5B is a sectional view of an example of a semiconductor device according to the present invention;

FIG. 6 is a graph showing the relationship between the thickness of the sacrifice film and the edge of the local channel;

FIG. 7 is a graph showing the relationship between the implantation energy and the critical film thickness;

FIG. 8 is a graph showing germanium implantation effect in the sacrifice film;

FIG. 9A is a sectional view of a semiconductor device manufactured according to the present invention;

FIG. 9B is a sectional view of a semiconductor device manufactured according to the present invention;

FIG. 9C is a sectional view of a semiconductor device manufactured according to the present invention;

FIG. 9D is a sectional view of a semiconductor device manufactured according to the present invention;

FIG. 9E is a sectional view of a semiconductor device manufactured according to the present invention;

FIG. 9F is a sectional view of a semiconductor device manufactured according to the present invention;

FIG. 9G is a sectional view of a semiconductor device manufactured according to the present invention;

FIG. 9H is a sectional view of a semiconductor device manufactured according to the present invention;

FIG. 9I is a sectional view of a semiconductor device manufactured according to the present invention;

FIG. 9J is a sectional view of a semiconductor device manufactured according to the present invention;

FIG. 9K is a sectional view of a semiconductor device manufactured according to the present invention;

FIG. 9L is a sectional view of a semiconductor device manufactured according to the present invention;

FIG. 9M is a sectional view of a semiconductor device manufactured according to the present invention; and

FIG. 9N is a sectional view of a semiconductor device manufactured according to the present invention.

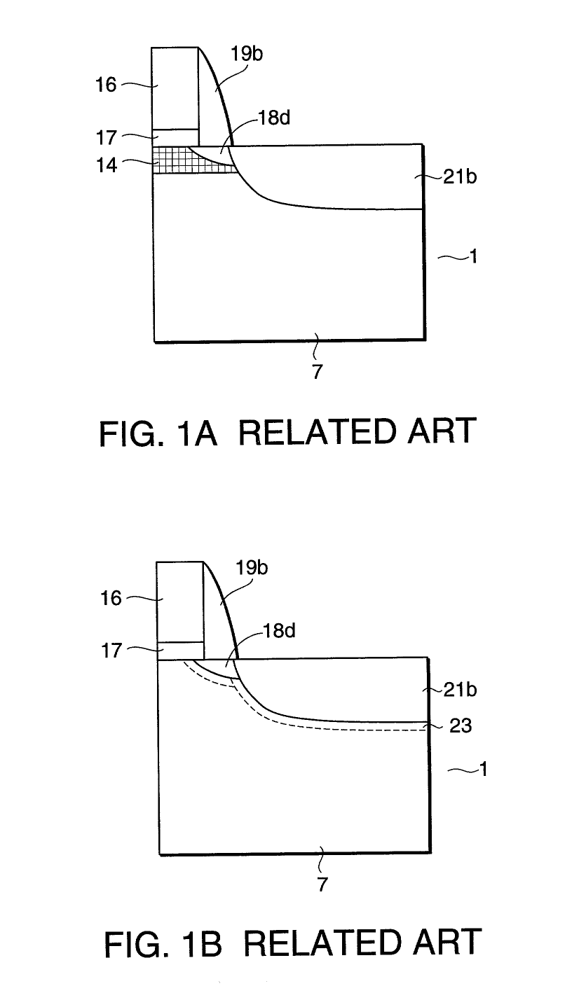

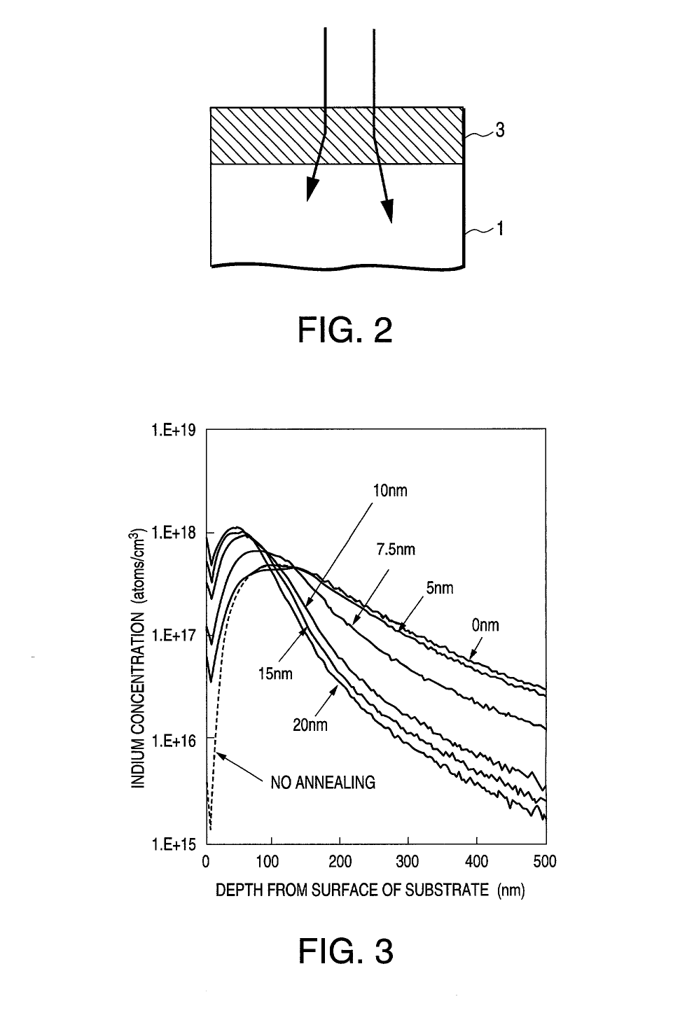

### BRIEF DESCRIPTION OF THE INVENTION

During the manufacturing a semiconductor device in accordance with the present invention, ion implantation is performed from a direction substantially perpendicular to a semiconductor substrate. The meaning “substantially perpendicular” is to perform the implantation from a direction perpendicular with respect to a plane including an element forming surface of a semiconductor substrate, for example, within 2 degrees, preferably within 1 degree from the perpendicular direction. It is most preferable to perform the implantation from the direction that coincides with the perpendicular direction with respect to the semiconductor substrate.

In the present invention, various films, which are effective to scatter the implanted ions, can be used as the materials composing the sacrifice film. For example, silicon oxide film, silicon nitride film or silicon oxynitride film can be used. When a silicon oxide film is used, conventional methods such as thermal oxidation or plasma CVD can be used as a film formation method. When a silicon nitride film is used, conventional methods such as LPCVD or plasma CVD can be used. If a silicon oxide film formed by thermal oxidation is used as the sacrifice film, implanted ions are effectively scattered.

In the present invention, the thickness of the sacrifice film is set within a predetermined range. For example, the film thickness is set as greater than or equal to 10 nm and less than or equal to 100 nm. The lower limit is preferably set to 15 nm, and more preferably 20 nm. If the thickness of the film is set within the above range, a scattering effect of the implanted ions may satisfactory be obtained, and the occurrence of channeling can be effectively prevented. Note that, depending on the process, it may be necessary to remove resist film several times after the sacrifice film is formed. In this case, however, it is preferable to form a thicker sacrifice film, taking into consideration the decrease in thickness of the film due to the resist film removing process. For example, in a CMOS process or the like, the lower limit of the film thickness of the sacrifice film is preferably 20 nm, and more preferably 25 nm.

On the other hand, the upper limit of the sacrifice film thickness can be appropriately set according to the condition of the ion implantation so that the peak of the impurity concentration appears at a position lower than the sacrifice film. The upper limit is normally 100 nm, and more preferably 70 nm.

In the case of using a silicon oxide film formed by a thermal oxidation method as a sacrifice film, the thickness is determined so that an equation d≧0.035V+4.75 is satisfied. In the equation, d (nm) is the thickness of the sacrifice film and V (keV) is the implantation energy upon the ion implantation. With the sacrifice film having a thickness in the above range, scattering effect of the implanted ions may sufficiently be obtained, and channeling can be effectively prevented. Note that, a silicon oxide film formed by the thermal oxidation method is relatively dense, and therefore the implanted ions can be suitably scattered.

In the present invention, if germanium or silicon is doped in the sacrifice film as an impurity, channeling is prevented more effectively. This is because the implanted ions for the formation of a local channel collide with germanium or silicon to be scattered. It is preferred that the introduction of germanium or silicon be performed by ion implantation. By doing so, in addition to the effect of implantation of germanium or silicon, it is possible to cause defects in crystal lattices in the sacrifice film. As a result, the implanted ion may be scattered more effectively.

The impurity to be doped in the sacrifice film is preferably germanium or silicon, and more preferably, particularly, germanium. Because germanium has a moderate large atomic radius, it collides easily with the implanted ions for forming the local channel. The inventors of the present invention have investigated the use of boron and fluorine as well. However, they confirmed that the channeling prevention effect could not be sufficiently attained when boron or fluorine is used as an impurity doped in the sacrifice film.

In order to dope germanium before the ion implantation, a technique is known in which the surface of the silicon substrate is pre-amorphized by implanting ions such as germanium, thereby preventing the occurrence of channeling. In this method, ions with a dose on the order of 1×10¹⁵ to 1×10¹⁶ cm⁻² are implanted without forming a sacrifice film or through a sacrifice film having a thickness of 5 nm. For the purpose of destroying a silicon crystal in order to amorphize, a sacrifice film is made thinner or ions are implanted directly into the substrate. The dosage must be set as relatively large. The channeling prevention effect may be attained to a given extent through this method. However, it is known that enhanced diffusion easily occurs, and this is associated with the diffusion of the secondary defects remaining at the interface between the amorphous and crystal or the diffusion of the lattice defects produced in mass (for example, described in “Handotai Daijiten (first edition), Kabushiki Kaisha Kogyo Chousakai, published in Dec. 10, 1999”, etc.). The present invention effectively prevents the occurrence of channeling while avoiding enhanced diffusion. Therefore, conversely to the above technique, an impurity such as germanium is implanted to the sacrifice film while preventing the amorphizing of the substrate and suppressing the damage of the substrate to the lowest limit. For that reason, in the present invention, the sacrifice film is formed into a thickness greater than or equal to 10 nm. Because the sacrifice film is thick, impurity elements such as germanium may be effectively implanted into the film, and the damage of the substrate can be suppressed to the minimum. In order to prevent the damage of the substrate more effectively, it is preferred to set appropriate conditions for implanting impurities such as germanium. For example, when germanium is doped by ion implantation, the upper limit of the dose is preferably 5×10¹⁴ cm⁻² or less, and more preferably, 1×10¹⁴ cm⁻² or less. The lower limit thereof is preferably 1×10¹³ cm⁻² or more, and more preferably, 5×10¹³ cm⁻² or more. With the above conditions, the amorphization of the substrate can be prevented and the defects of the substrate can be suppressed to a minimum.

In the present invention, a particularly remarkable effect may be attained when indium is used as an ion species for the ion implantation. Indium is a relatively heavy element, so even if a thermal process is performed after indium is implanted into a silicon substrate, indium does not move easily. Thus, the enhanced diffusion of indium is not liable to occur, whereas the channeling is liable to occur, due to the fact that indium is used. In the present invention, a sacrifice film with a predetermined thickness is provided so that the channeling does not easily occur. Therefore, even if indium is used (for which enhanced diffusion does not easily occur), channeling can be effectively prevented. A steep impurity concentration distribution with a precise positioning can be provided.

When manufacturing a semiconductor device according to the present invention, the semiconductor device has a structure such that an impurity doped region (a local channel) is formed by ion implantation, and thereafter a gate electrode is formed on the surface of the semiconductor substrate. Source and drain regions having a conductivity type opposite to the local channel are formed on both sides of the gate electrode so as to contact with the local channel. According to this manufacturing method, the source and drain regions and the local channel having a conductivity type opposite thereto are formed with a positional relationship adjacent with each other. Therefore, parasitic resistance, which has been a problem in conventional techniques, can be prevented from occurring at the edges of the source and drain regions, and short-channel effects are effectively suppressed. In order to form the local channel having such characteristics, it is necessary to prevent the occurrence of enhanced diffusion while preventing the occurrence of channeling, and to form a local channel having a steep impurity concentration distribution with a precise positioning. However, in the present invention, a sacrifice film with a predetermined thickness is used, thereby making it is possible to realize a local channel showing the above characteristics in reply to the above-mentioned requirements.

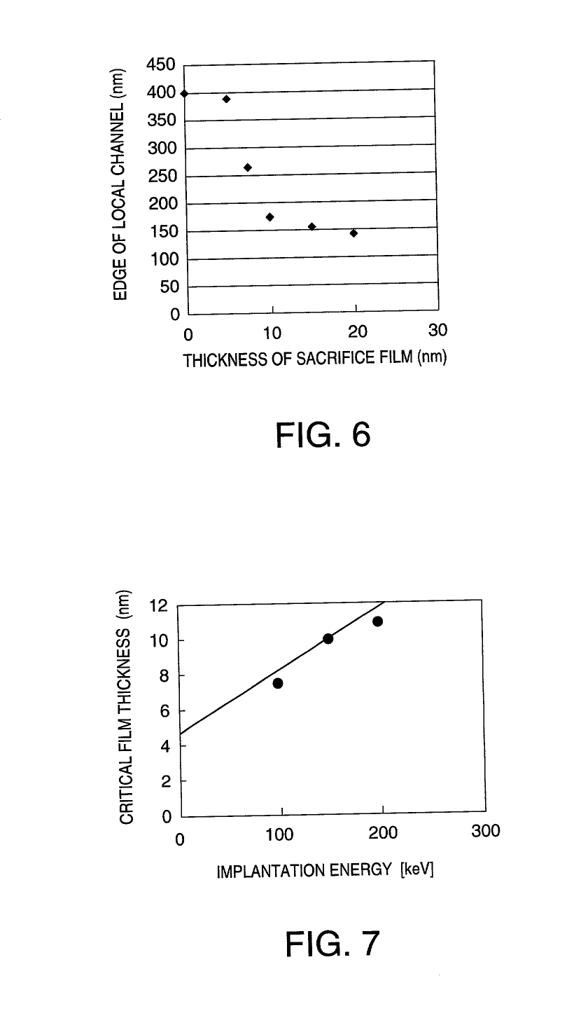

Next, the structure of the semiconductor device according to the present invention is explained with reference to the figures. FIG. 4 shows an example in which the present invention is applied to CMOS. In the figure, an NMOS is formed on the left side and a PMOS is formed on the right side. An element separation film 2, an n-type well 7, and a p-type well 8 are provided on a silicon substrate 1. Source and drain regions are provided in each well. The source and drain regions comprise highly doped source regions 20a and 20b, highly doped drain regions 21a and 21b, and lightly doped extension regions 18a, 18b, 18c, and 18d. Gate electrodes 16a and 16b are provided on the surface of the substrate, and sidewalls 19a and 19b are provided on both sides of the gate electrodes. Local channels 12 and 14 are provided so as to contact with the extension regions 18a, 18b, 18c, and 18d and a part of the highly doped source and drain regions 20a, 20b, 21a, and 21b. The edge portion of the local channel shown in FIG. 4 is positioned so that the edge becomes a position at which the concentration of impurity is one tenth of the impurity peak concentration. By providing local channels in such manner, the occurrence of parasitic resistance in the vicinity of the extension regions is prevented, and short-channel effects are effectively prevented.

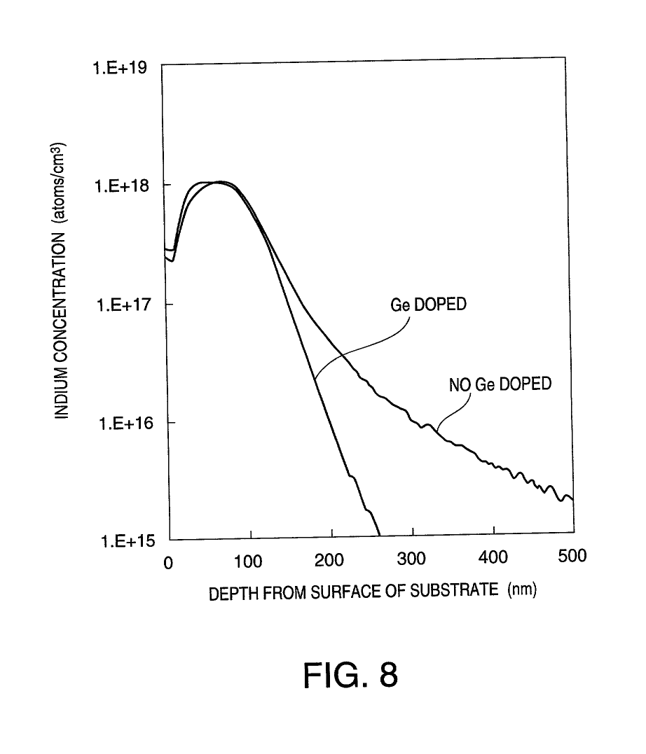

The local channel can have different forms than the one described above. FIGS. 5A and 5B show other embodiments of the present invention. In FIG. 5A, a local channel 12, 14 is provided in a broad region so as to contact with the highly doped source regions 20a and 20b, and highly doped drain regions 21a and 21b. With this structure, a short-channel effect can be prevented more effectively. On the other hand, in FIG. 5B, a local channel 12 and 14 is provided so as to contact with only to extension regions 18a, 18b, 18c and 18d. When a local channel is formed so as to contact the highly doped source and drain regions, a leakage current may easily occur at the interface. Therefore, the suppression of a leakage current is taken seriously, it is preferable to employ such a structure.

Embodiment 1

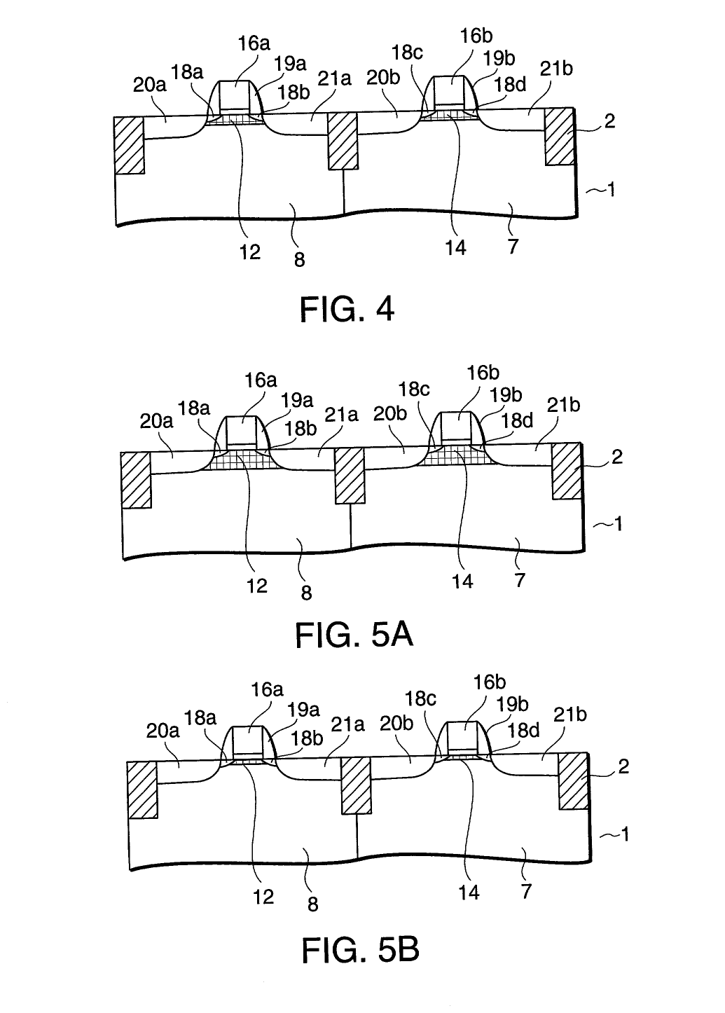

A sacrifice film comprising silicon oxide film is formed by a thermal oxidation method (substrate temperature 800° C.). Ion implantation is performed through the sacrifice film to form a local channel, and the impurity concentration distribution is then measured. The measurement result is shown in FIG. 3. This impurity concentration is obtained after annealing, and data (without sacrifice film) shown by a dotted line, which is described as “no annealing,” is the impurity concentration distribution before annealing. Because the movement of indium before and after annealing is small, the indium concentration profile shown in FIG. 4 is almost identical to the profile right after the ion implantation. The film thickness shown in FIG. 4 is the thickness of the sacrifice film only. The condition of the ion implantation are as follows:

Substrate: Silicon (100) crystal

Implantation angle: 0 degrees (implanted from a direction perpendicular to the silicon substrate)

Ion species: indium

Acceleration voltage: 150 keV

Dosage: 1×10¹³ cm⁻²

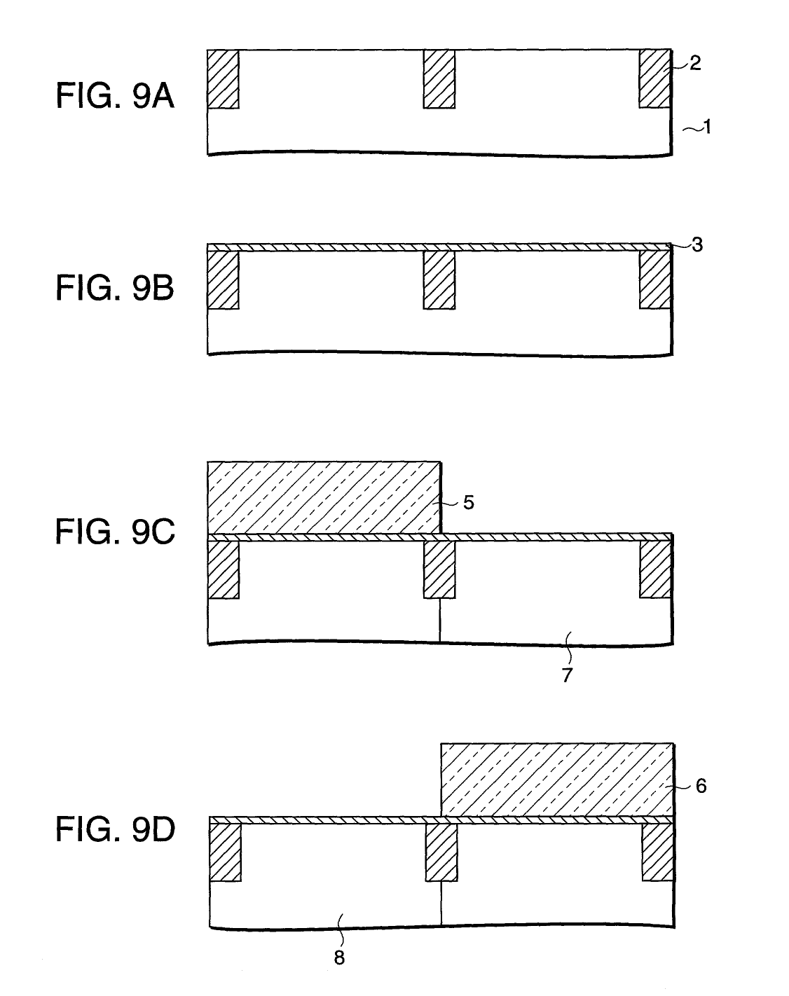

FIG. 6 shows a relationship between the thickness of the sacrifice film and the edge of the local channel, according to the measurement results of FIG. 3. In this case, a point where the impurity concentration equivalents to one tenth of the peak concentration is defined as the edge of the local channel, and the point is indicated in accordance with a distance from the surface of the substrate. In the case of a 15 nm thick sacrifice film, in FIG. 3 for instance, the impurity peak concentration is 1×10¹⁸ cm⁻³. Therefore, at a point that is 156 nm deep, where the concentration equivalents to one tenth of the peak concentration of 1×10¹⁷ cm⁻³, is the edge of the local channel. The position of the edge of the local channel is as shallow in depth, and the impurity concentration distribution becomes steep. As shown in FIG. 6, when the thickness of the sacrifice film exceeds 10 nm, the impurity concentration distribution becomes extremely steep and the prevention of channeling is remarkably developed. The thickness of the sacrifice film at which the channeling prevention effect is remarkably developed is referred to as “the critical film thickness.” It can be understood that, when the sacrifice film becomes thicker than a certain thickness, an accumulated collision probability between the doped ions and atoms constituting the sacrifice film abruptly increases, and an order in the crystal of the sacrifice film becomes satisfactory.

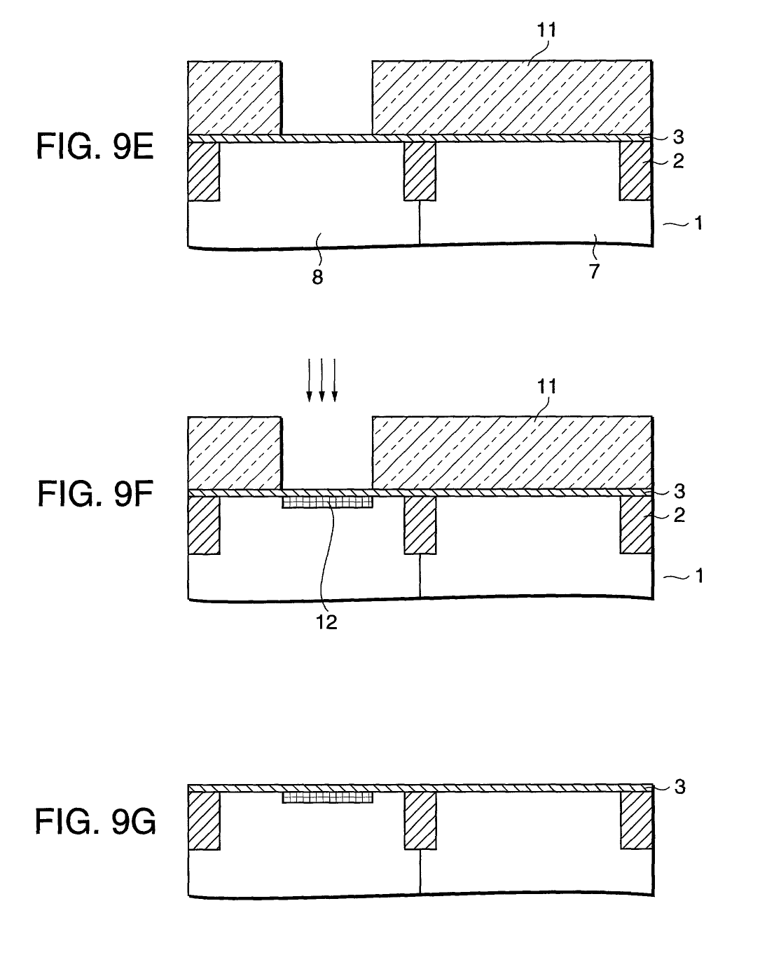

The critical film thickness differs depending on the acceleration voltage of the ion implantation. FIG. 7 shows the relationship between the acceleration voltage of the ion implantation and the critical film thickness when a silicon oxide film is used as a sacrifice film. When the acceleration voltage and the thickness of the sacrifice film are set so as to satisfy d≧0.035V+4.75 (a region above the straight line in the figure), where d (nm) is the thickness of the sacrifice film and V (keV) is the ion implantation energy, the film thickness is thicker than the critical film thickness. When the acceleration voltage and the thickness of the sacrifice film satisfy this equation, the occurrence of channeling is prevented. Preferably, as in the experiment shown in FIG. 3, the acceleration voltage of the ion implantation is typically set to greater than or equal to 150 keV. Therefore, channeling can be prevented when the thickness of the sacrifice film is set as more than or equal to 10 nm.

Embodiment 2

Using two silicon wafers made of a silicon (110) crystal, a silicon oxide film (approximate film thickness 15 nm) is formed on each wafer by the thermal oxidation at the substrate temperature of 800° C. Then, germanium is doped into one silicon wafer only by ion implantation. The conditions of the germanium implantation are as follows:

Implantation angle: 0 degrees (doped from a direction perpendicular to the silicon substrate)

Acceleration voltage: 100 keV

Dosage: 5×10¹⁴ cm⁻².

Then, the silicon oxide film is used as a sacrifice film, and indium is doped by ion implantation to obtain the impurity concentration distribution. The condition of indium implantation is as follows:

Implantation angle: 0 degrees (doped from a direction perpendicular to the silicon substrate)

Acceleration voltage: 150 keV

Dosage: 1×10¹³ cm⁻²

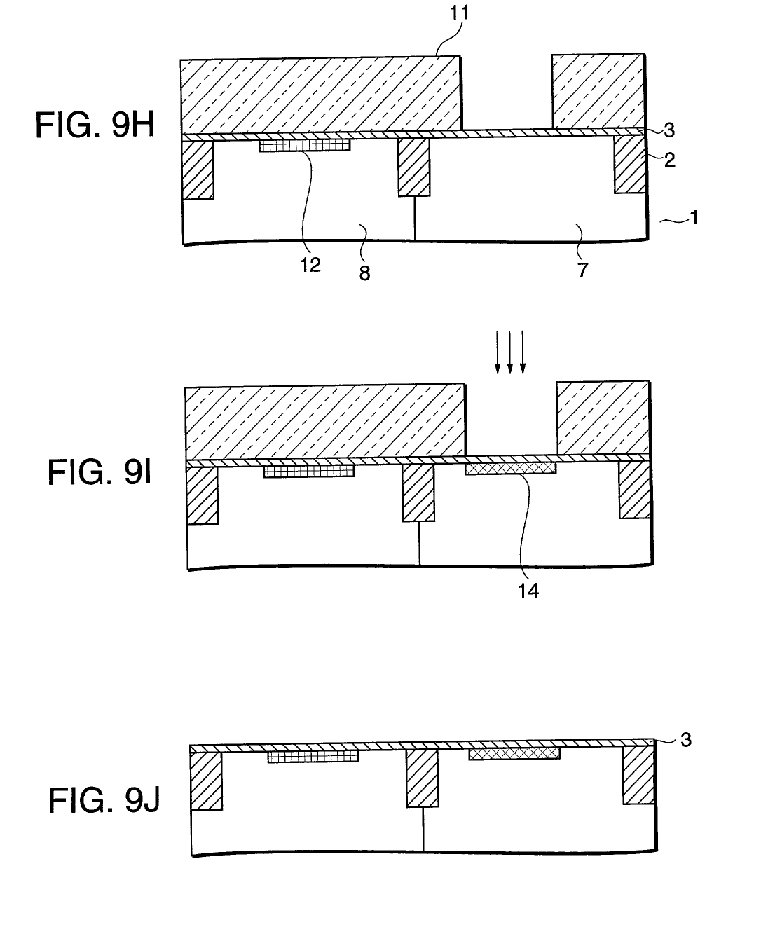

The measurement results of the impurity concentration distribution are shown in FIG. 8. The impurity concentration is measured after annealing. Because the movement of indium before and after annealing is small, it can be considered that an indium concentration profile shown in FIG. 8 is almost identical to the profile right after the ion implantation. It is clear from FIG. 8 that doping germanium in the sacrifice film adds the effect of preventing channeling in addition to the effect from making the film thicker. When comparing FIG. 3 (a distribution with 15 nm film thickness) to FIG. 8 (a distribution with germanium doped in the film), the abruptness of the impurity concentration may be improved when germanium is doped in the sacrifice film.

The substrate after germanium is doped is observed with a transmission type electron microscopy. It is confirmed that there is no disorder in the crystal of the surface of the substrate.

Embodiment 3

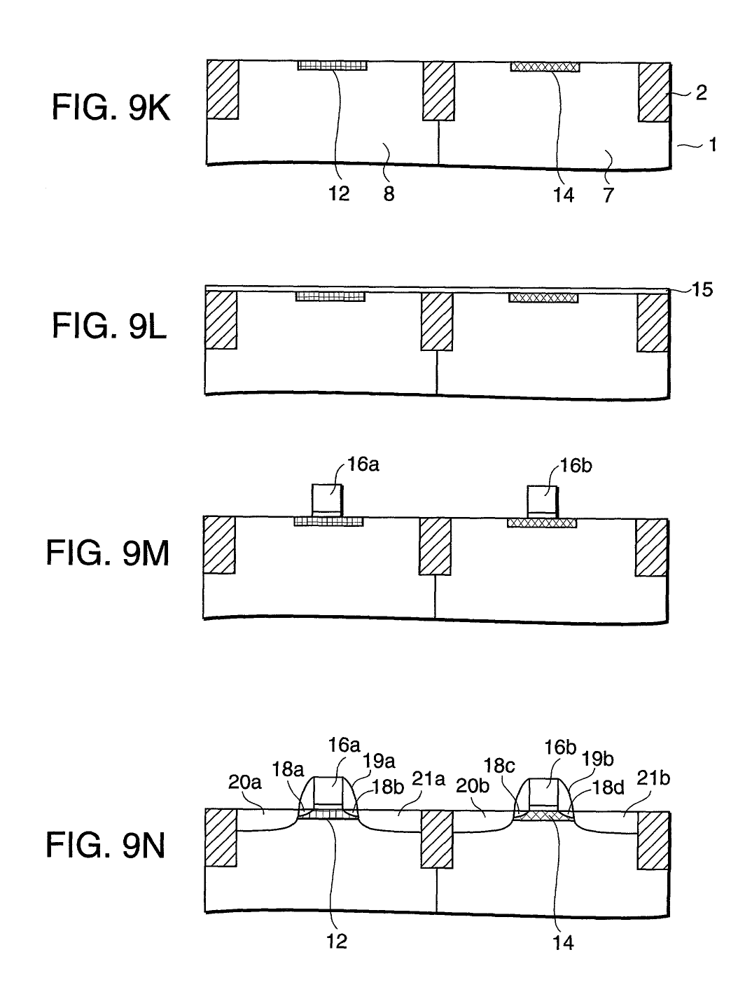

The structure of a CMOS device is in accordance with the structure shown in FIG. 4. The transistor shown in the FIG. 4 differs from the conventional transistor because it has local channels 12 and 14. The manufacturing method of this CMOS is explained with reference to FIGS. 9A to 9N. Note that, in the description hereinafter, a temperature of heat treatment is a substrate temperature measured without contact by a pyrometer.

First, as shown in FIG. 9A, an element separation film 2 is provided on a silicon substrate 1 by means of STI (Shallow Trench Isolation). Then, a sacrifice film 3 is provided on the entire surface of the substrate by a thermal oxidation method with a substrate temperature of approximately 850° C. The film thickness is approximately 250 nm, as shown in FIG. 9B.

Next, as shown in FIG. 9C, a resist film 5 is formed on a pMOS forming region (the left of the figure), boron is doped in an nMOS forming region (the right of the figure) by ion implantation to provide a p-type well 7.

After the resist film 5 is removed by ashing and a stripping solution processing, as shown in FIG. 9D, a resist film 6 is formed on an nMOS transistor forming region (the right of the figure). Arsenic is doped in an NMOS forming region (the right of the figure) using the resist film 6 as a mask by ion implantation to provide an n-type well 8.

As shown in FIG. 9E, after a resist film 6 is removed by ashing and a stripping solution processing, a resist film 11 having an opening is formed on a part of the pMOS transistor forming region. As shown in FIG. 9F, using resist film 11 as a mask, arsenic is doped by ion implantation. The conditions of the ion implantation are, for example, an acceleration voltage 100 keV and a dosage 1×10¹³ cm⁻². The ion implantation angle is set as a direction perpendicular to the substrate. With this ion implantation, a local channel 12 is formed.

The resist film 11 is next removed by ashing and a stripping solution processing, the state in which the resist film 11 is removed is shown in FIG. 9G. The sacrifice film 3 is initially set as 25 nm thick. However, the thickness decreases to approximately 15 to 20 nm at the stage shown in FIG. 9G, because the sacrifice film 3 has been exposed to the removal of resist films three times.

Next, as shown in FIG. 9H, a resist film 13 having an opening is formed on a part of pMOS forming region (FIG. 9H). Then, as shown in FIG. 9I, using the resist film 13 as a mask, indium is doped by ion implantation. The conditions of the ion implantation are, for example, an acceleration voltage 150 keV and a dosage 1×10¹³ cm⁻². With this ion implantation, a local channel 14 is formed.

Then, the resist film 14 is removed by ashing and a stripping solution processing, and the removed state is shown in FIG. 9J.

As shown in FIG. 9K, the sacrifice film 3 is removed by wet etching. As shown in FIG. 9L, a gate insulating film 15 made of a 2.6 nm thick silicon oxynitride film is provided on the surface of the substrate 1. The silicon oxynitride film is formed by creating a silicon oxide film, annealing it in a NO atmosphere, and then oxidizing it again if necessary. A polycrystal silicon 16 is deposited on the gate insulating film 15. As shown in FIG. 9M, patterning the gate insulating film 15 and the polycrystal silicon 16 by selective etching provides gate electrodes 16a and 16b. Typically, the length of the gate electrode is set as 0.13 μm, but the process used determines the actual length.

Then, after extension regions 18a and 18b are formed in the nMOS region by ion implantation, extension regions 18c and 18d are formed in the pMOS region by the ion implantation. For example, the conditions of the ion implantation to form the extension regions 18a and 18b use boron as the ion species, with an approximate acceleration voltage 1 to 2 keV, and an approximate dosage of 5×10¹⁴ to 1×10¹⁵ cm⁻². The conditions of the ion implantation to form the extension regions 18c and 18d use arsenic as the ion species, with an approximate acceleration voltage 2 to 5 keV, and an approximate dosage of 5×10¹⁴ to 1×10¹⁵ cm⁻².

Then, after sidewalls 19a and 19b are formed, a source region 20a and a drain region 21a are formed in the nMOS region by ion implantation. Typical conditions for the ion implantation use a boron ion species, with an approximate acceleration voltage 2 to 3 keV, and an approximate dosage of about 3×10¹⁵ cm^{-2.}

Thereafter, a source region 20b and a drain region 21b are formed. Again, typical conditions for the ion implantation use an arsenic ion species arsenic, with an approximate acceleration voltage 20 to 30 keV, and an approximate dosage of about 3×10¹⁵ cm⁻².

Next, heat treatment by rapid thermal annealing (RTA) is performed. Note that a step of forming a pocket region may be performed between the step of forming the extension regions and the step of forming the source and drain regions.

From the above steps, a structure as shown in FIG. 9N is obtained. Then, after providing a cobalt film by sputtering on the entire substrate, a cobalt silicide film is provided by subjecting the cobalt film to heat treatment, and an inter-layer insulating film is provided on top. Then, a contact plug in which tungsten is buried is provided, and forming upper wiring layers completes the CMOS device.

By performing the above-mentioned processes, a CMOS device with high reliability is obtained. Please note that it is possible to appropriately change the order of forming PMOS and NMOS, and the order of forming PMOS local channel and NMOS local channel.

As described above, according to the present invention, the thickness of the sacrifice film is appropriately set, and the element which causes scattering of ions is implanted in the film, thereby effectively preventing the channeling of implanted ions. Moreover, by selecting a heavy element such as indium, enhanced diffusion can be prevented as well. The present invention allows the steep impurity concentration distribution is formed with a precise positioning.

When the present invention is applied to form a local channel under the gate electrode, the occurrence of parasitic resistance at the edges of the source and drain regions can be prevented. This is a problem inherent in the conventional technique, and short-channel effects can be suppressed as well. To form a local channel having such characteristics, it is required to prevent enhanced diffusion as well as channeling, and to form a steep impurity concentration distribution with a precise positioning. However, according to the present invention, a technique using a sacrifice film with a predetermined thickness is capable of forming the local channel with characteristics that satisfy the requirements described above.

The present invention is not limited to the above embodiments, and it is contemplated that numerous modifications may be made without departing from the spirit and scope of the invention. The method of the formation of the local channel, as described above with reference to the drawings, is a merely an exemplary embodiment of the invention, and the scope of the invention is not limited to these particular embodiments. Accordingly, other method may be used, without departing from the spirit and scope of the invention as defined in the following claims.

What is claimed is:

1. A method of manufacturing a semiconductor device, comprising:
providing a sacrifice film having a thickness greater than or equal to 10 nm and less than or equal to 100 nm on a semiconductor substrate;
providing a resist film having an opening on said sacrifice film; and
providing an impurity doped region by performing an ion implantation through said sacrifice film from a direction substantially perpendicular to said semiconductor substrate with using said opening in said resist film as a mask.

2. The method of manufacturing a semiconductor device as claimed in claim 1, wherein said sacrifice film is a silicon oxide film.

3. The method of manufacturing a semiconductor device as claimed in claim 2, wherein said sacrifice film is formed by thermal oxidation.

4. The method of manufacturing a semiconductor device as claimed in claim 1, wherein said impurity doped region is formed under a condition of d≧0.035V+4.75, where d (nm) is said thickness of said sacrifice film and V (keV) is an implant energy of said ion implantation.

5. The method of manufacturing a semiconductor device as claimed in claim 1, further comprising implanting an impurity into said sacrifice film so as to make a defect in said sacrifice film.

6. The method of manufacturing a semiconductor device as claimed in claim 5, wherein said implanting an impurity into said sacrifice film is performed so as to prevent said semiconductor substrate from having a defect.

7. The method of manufacturing a semiconductor device as claimed in claim 5, wherein said impurity implanted into said sacrifice film is silicon.

8. The method of manufacturing a semiconductor device as claimed in claim 5, wherein said impurity implanted into said sacrifice film is germanium.

9. The method of manufacturing a semiconductor device as claimed in claim 8, wherein a dosed amount of said germanium is between 1×10^{—}cm⁻² and 5×10¹⁴ cm⁻².

10. The method of manufacturing a semiconductor device as claimed in claim 1, wherein said impurity doped region comprises indium.

11. The method of manufacturing a semiconductor device as claimed in claim 1, wherein said impurity doped region is a local cannel region, the method further comprising:
providing a gate electrode on said semiconductor substrate; and
providing a source region and a drain region, at both sides of said gate electrode so that said source region and said drain region contact with said local channel.

12. The method of manufacturing a semiconductor device as claimed in claim 11, wherein:
said source region comprises a highly doped region and an extension region, and
said local channel contacts with said highly doped region and said extension region.

13. The method of manufacturing a semiconductor device as claimed in claim 11, wherein:
said source region comprises a highly doped region and an extension region, and
said local channel contacts with said extension region.

14. The method of manufacturing a semiconductor device as claimed in claim 1, wherein said direction is less than 2 degrees from perpendicular relative to said semiconductor substrate.

15. The method of manufacturing a semiconductor device as claimed in claim 1, wherein said impurity doped region is one of a group consisting indium, arsenic or phosphorus.

16. A method of manufacturing a semiconductor device, comprising:
providing a sacrifice film on a semiconductor substrate;
providing a resist film having an opening on said sacrifice film; and
providing an impurity doped region by performing an ion implantation through said sacrifice film from a direction substantially perpendicular to the semiconductor substrate with using said opening in said resist film as a mask, under a condition of d≧0.035V+4.75, where d (nm) is a thickness of said sacrifice film and V (keV) is an implant energy upon said ion implantation.

17. The method of manufacturing a semiconductor device as claimed in claim 16, wherein said sacrifice film is a silicon oxide film.

18. The method of manufacturing a semiconductor device as claimed in claim 16, wherein said sacrifice film is formed by thermal oxidation.

19. The method of manufacturing a semiconductor device as claimed in claim 16, further comprising implanting an impurity into said sacrifice film.

20. The method of manufacturing a semiconductor device as claimed in claim 19, wherein said impurity doped into said sacrifice film is germanium.

21. The method of manufacturing a semiconductor device as claimed in claim 19, wherein said impurity doped into said sacrifice film is silicon.

22. The method of manufacturing a semiconductor device as claimed in claim 20, wherein a dosed amount of said germanium is between 1×10¹³ cm⁻² and 5×10¹⁴ cm⁻².

23. The method of manufacturing a semiconductor device as claimed in claim 16, wherein said impurity doped region comprises indium.

24. The method of manufacturing a semiconductor device as claimed in claim 16, wherein said impurity doped region is one of a group consisting indium, arsenic or phosphorus.
